(19) United States
(12) Patent Application Publication
(10) Pub. No.: US 2024/0211087 A1
(43) Pub. Date: Jun. 27, 2024

(54) TOUCH DISPLAY PANEL AND DISPLAY DEVICE

(71) Applicants: Chengdu BOE Optoelectronics Technology Co., Ltd., Sichuan (CN); BOE Technology Group Co., Ltd., Beijing (CN)

(72) Inventors: Yuanqi Zhang, Beijing (CN); Ping Wen, Beijing (CN); Shun Zhang, Beijing (CN); Yi Zhang, Beijing (CN); Chang Luo, Beijing (CN)

(73) Assignees: Chengdu BOE Optoelectronics Technology Co., Ltd., Sichuan (CN); BOE Technology Group Co., Ltd., Beijing (CN)

(21) Appl. No.: 17/915,784

(22) PCT Filed: Oct. 22, 2021
(86) PCT No.: PCT/CN2021/125659

§ 371 Date: Sep. 29, 2022

(30) Foreign Application Priority Data
Apr. 30, 2021 (CN) 202110487995.9

(51) Int. Cl. G06F 3/045; G06F 3/044; H10K 59/40; G06F 3/041

(52) U.S. Cl. CPC G06F 3/045; G06F 3/044; H10K 59/40; G06F 3/0412; G06F 2203/04107

(57) ABSTRACT

The present disclosure provides a touch display panel, in which a touch layer comprises a trace line and a crack detection line. There is a group of wires in a first direction in a lower frame area of the touch display panel, wherein the group of wires in the first direction comprises a trace part which is a portion of trace line extending in the first direction and a first crack detection part which is a portion of the crack detection line extending in the first direction; wherein a maximum distance between the first crack detection part and the trace part is less than 10 times a width of the trace part in a direction perpendicular to its extending direction.

### CROSS REFERENCE TO RELATED APPLICATION(S)

This application is a Section 371 National Stage Application of International Application No. PCT/CN2021/125659, which claims priority to Chinese Patent Application No. 202110487995.9 filed on Apr. 30, 2021, and the contents of which are incorporated herein by reference in its entirety.

### TECHNICAL FIELD

The present disclosure relates to the technical field of display, and particularly to a touch display panel and a display device.

### BACKGROUND

A display panel is a multilayer thin-film device, and its manufacture process comprises depositing various thin-film layers on a substrate to finally achieve the display function. A local crack is likely to occur due to the differences in hardness and tension between various thin-film layers. Furthermore, a crack may occur or an existing crack may be deepened also during the film coating, transferring, testing, assembling and transporting of the panel.

The occurrence of cracks on the periphery of the display panel is a defect commonly seen in the manufacture process. For this issue, a Panel Crack Detection (PCD) circuit design is incorporated in the design of some display panels. The testing principle of the PCD circuit mostly lies in an impedance test, and the main body for testing is typically a metal line disposed on the periphery of the display panel. If a crack passes a portion where the metal line is located, the metal line there will turn to an open circuit state from a conducting state, such that the resistance of the PCD circuit will vary. The resistance change of the PCD circuit may be measured by means of signal detection or lighting on. For example, a line may be disposed on the periphery of the display panel, and whether there is a crack is determined by measuring the resistance change of the line disposed on the periphery. Alternatively, a line may be disposed on the periphery of the display panel and connected to a pixel circuit of the active area (AA), and whether there is a crack is determined by the presence or absence of a bright line or a dark line when lighting on.

The Flexible Multilayer On Cell (FMLOC) technology has been increasingly applied in the technical field of display, particularly in a touch display device. The flexible multilayer structure may be used to form a touch layer. A typical FMLOC film comprises auxiliary layers such as a first metal layer (Metal 1), an insulator layer (Insulator), a second metal layer (Metal 2), a barrier layer (Barrier), and an overcoat layer (OC). In contrast to a conventional out-cell touch panel product which is externally hanged on the display panel, these film layers are directly fabricated on the encapsulation film layer of a base display panel by processes such as deposition, exposure, development and etching, such that they are integrated with the base display panel, which is beneficial for the thinning of the display device. Currently, the PCD circuit designed has been incorporated into the FMLOC design, that is, the first metal layer (Metal 1) and/or the second metal layer (Metal 2) in the FMLOC are utilized to fabricate the PCD line, which may be referred to as an FMLOC PCD. The FMLOC PCD design mainly aims at performing a PCD examination in the panel-processing stage or the module-processing stage after forming the FMLOC film layers. It may be known from the PCD examination whether the PCD line is broken, thereby knowing whether there is a crack extending to the region of the PCD line in the frame of the display panel.

There is still a need for improvement in the display panel design comprising an FMLOC PCD line.

### SUMMARY

In an aspect, the present disclosure provides a touch display panel, wherein,
the touch display panel comprises an active area and a frame area surrounding the active area, wherein the frame area comprises a lower frame area below the active area, the lower frame area of the touch display panel comprises a first main body, a bending region and a second main body, and the second main body is bent to a back side opposite to a display side of the touch display panel,
the touch display panel comprises a base display panel and a touch layer on the base display panel, wherein the touch layer comprises a touch electrode disposed in the active area, an trace line connected to the touch electrode and disposed in the frame area, and a crack detection line at a side of the trace line away from the active area, and in the first main body, the trace line comprises at least one conductive layer which is in the same layer as a conductive layer of the crack detection line, and
there is a group of wires in a first direction in the first main body, wherein the first direction is a direction from the active area to the lower frame area, and the group of wires in the first direction comprises a trace part which is a portion of the trace line extending in the first direction, and a first crack detection part which is a portion of the crack detection line extending in the first direction;
wherein a maximum distance between the first crack detection part and the trace part is less than 10 times a width of the trace part in a direction perpendicular to its extending direction.

Optionally, the group of wires in the first direction further comprises a guard line, wherein the guard line comprises a conductive layer which is in the same layer as the conductive layer of the trace line, and is located between the first crack detection part and the trace part, an electrical signal the same as that of the trace line is input to the guard line.

Optionally, the group of wires in the first direction further comprises a ground line, wherein the ground line comprises a conductive layer which is in the same layer as the conductive layer of the trace line, and is at a side of the guard line away from the trace part.

Optionally, the group of wires in the first direction further comprises a dummy trace line, wherein the dummy trace line comprises a conductive layer which is in the same layer as the conductive layer of the first crack detection part, and is at a side of the first crack detection part away from the trace part, and the dummy trace line is electrically floating.

Optionally, a number of the dummy trace line is 2 or more.

Optionally, all the lines in the group of wires in the first direction have the same line width and the same line distance.

Optionally, the line width is between 10 nm and 30 nm, and the line distance is between 15 nm and 30 nm.

Optionally, the first direction is perpendicular to a bending axis of the bending region.

Optionally, the touch layer comprises a first metal layer, an insulator layer and a second metal layer stacked one on top of another.

Optionally, the trace part comprises a first metal layer and a second metal layer connected in parallel, and the first crack detection part comprises at least one layer of the first metal layer and the second metal layer.

Optionally, the crack detection line comprises a second crack detection part at a side of the first crack detection part away from the bending region, wherein the second crack detection part is connected to the first crack detection part and extends in a second direction substantially perpendicular to the first direction; and
the second crack detection part comprises a first line segment and a second line segment alternately disposed in different layers, wherein an end of the first line segment and an end of the second line segment are overlapped with each other, and electrically connected to each other through a via hole in an insulator layer between the layers.

Optionally, the touch display panel comprises an extension line part extending from at least a portion of lines in the group of wires in the first direction to the second main body.

Optionally, the base display panel comprises a display structure and an encapsulation layer on the display structure, and the touch layer is disposed on the encapsulation layer.

Optionally, the second main body has a concave corner, and when the touch panel is in an unbent state, a distance between the crack detection part and the concave corner is 0.8 mm or more.

In another aspect, the present disclosure provides a display device comprising the above-mentioned touch display panel.

### BRIEF DESCRIPTION OF DRAWINGS

FIG. 1 shows a schematic diagram of a display panel comprising an active area and a lower frame area.

FIG. 2 shows a schematic section view of a touch panel comprising a base display panel and a touch layer as well as having a bending region.

FIG. 3 shows a schematic flow chart of an FMLOC process.

FIG. 4 schematically shows a touch electrode on a pixel of the active area.

FIG. 5 shows a section view of an embodiment of an FMLOC touch panel when it is entirely unbent.

FIG. 6 shows a principle diagram for the PCD examination.

FIG. 7 shows a schematic diagram of the line arrangement position in a conventional FMLOC comprising PCD lines in related technologies.

FIGS. 8(a)-(b) shows a schematic diagram of the relationship between the line arrangement position and the bending region in a conventional double layer structure.

FIG. 9 shows a partial enlarged view of FIG. 8(b) having a concave corner.

FIG. 10 shows a schematic diagram of the arrangement of PCD lines in the lower frame area in an embodiment of the present disclosure.

FIG. 11 shows a partial enlarged view of FIG. 10.

FIG. 12 shows a schematic diagram the jumper of PCD lines in an embodiment of the present disclosure.

### DETAILED DESCRIPTION

The present disclosure provides a touch display panel, which has decreased possibility of defect after an electrostatic discharge immunity test.

Specifically, the present disclosure provides a touch display panel, wherein,
the touch display panel comprises an active area and a frame area surrounding the active area, wherein the frame area comprises a lower frame area below the active area, the lower frame area of the touch display panel comprises a first main body, a bending region and a second main body, and the second main body is bent to a back side opposite to a display side of the touch display panel,
the touch display panel comprises a base display panel and a touch layer on the base display panel, wherein the touch layer comprises a touch electrode disposed in the active area, an trace line connected to the touch electrode and disposed in the frame area, and a crack detection line at a side of the trace line away from the active area, and in the first main body, the trace line comprises at least one conductive layer which is in the same layer as a conductive layer of the crack detection line, and
there is a group of wires in a first direction in the first main body, wherein the first direction is a direction from the active area to the lower frame area, and the group of wires in the first direction comprises a trace part which is a portion of the trace line extending in the first direction, and a first crack detection part which is a portion of the crack detection line extending in the first direction;
wherein a maximum distance between the first crack detection part and the trace part is less than 10 times a width of the trace part in a direction perpendicular to its extending direction.

The touch display panel of the present disclosure has a basic structure similar with that of a conventional FMLOC type touch display panel.

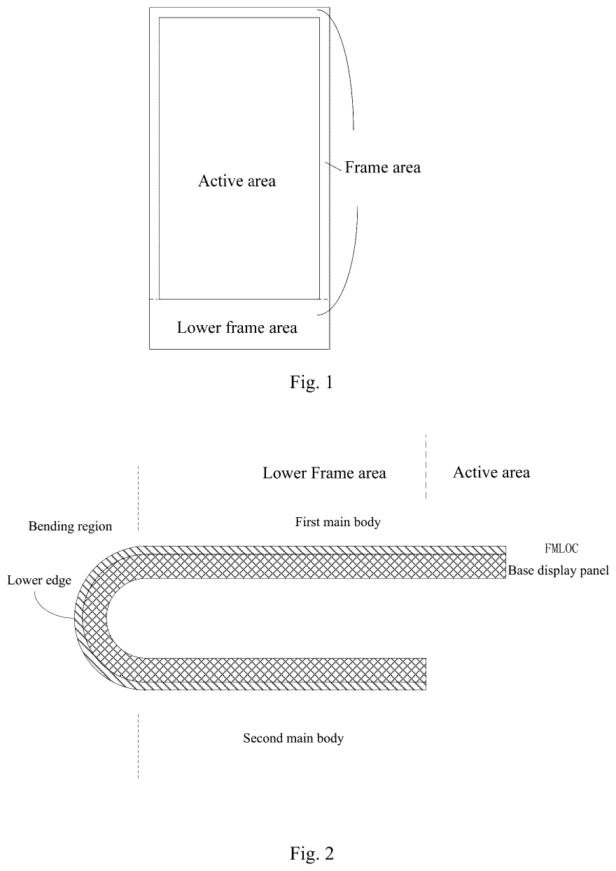

When viewing from the front side of the touch display panel, the touch display panel of the present disclosure comprises an active area and a lower frame area below the active area. The active area of the touch display panel is provided with light emitting pixels, and may display an image. The active area is surrounded by a frame area on the periphery. Typically, when viewing from the front side, the active area has a frame area on the entire periphery. Nevertheless, from the viewpoint of aesthetics, for some display panels, it is desired that the frame area is as narrow as possible. Therefore, for example, in applications such as a full screen mobile phone, the left, right and upper sides of the active area may not be provided with a frame area. Nevertheless, the display panel still needs to have at least one frame area for collectively accommodating circuits which are difficult to bend but necessary, and such a frame area is typically disposed below the active area. For example, even in current applications of full screen mobile phone, there is still a lower frame area which does not display any image in the lower part of the mobile phone. It should be understood that all the expressions “up”, “down”, “left”, “right”, “front” and “back” herein are only used to describe the relative position rather than the absolute position between parts. In the present disclosure, the expression “lower frame” is only used to conveniently describe the relative position, but does not means that it is necessarily disposed below the displayed image. Furthermore, although a conventional display panel has a rectangular shape, and the lower frame area is a rectangular area at one of its four sides, a display panel having another contour shape may also have a frame area of any shape in which circuits are collectively accommodated. Any frame having a collective circuit line arrangement in the display panel may be considered as a lower frame. When described in the present disclosure, it is specified to be disposed in a lower part, and the active area is disposed in an upper part accordingly. FIG. 1 shows a schematic diagram of a display panel comprising an active area and a lower frame area.

The touch display panel of the present disclosure comprises a base display panel and a touch layer on the base display panel. The touch layer may be an FMLOC (Flexible Multilayer On Cell) film. In the FMLOC film, a plurality of film layer are sequentially formed directly on the base display panel as a whole, thereby forming a touch layer overlaying the light-exiting side of the base display panel. A user watches an image displayed on the base display panel through the transparent touch layer, and presses the touch layer according to an image prompt to achieve the touch control. The FMLOC film is formed on the base display panel, and typically, can completely cover the base display panel, but can also cover only a portion thereof.

The lower frame area of the touch display panel of the present disclosure comprises a first main body, a bending region and a second main body, and the second main body is bent to a back side opposite to a display side of the touch display panel. FIG. 2 shows a section view in the vicinity of such a lower frame area of a touch display panel. In this figure, the upper side represents the front side of the touch display panel, and the left side corresponds to the lower side of the lower frame area when viewing from the front side of the touch display panel. The touch display panel comprises a double layer structure of an FMLOC film and a base display panel. The double layer structure has a portion bending toward the back side in the lower frame area, such that a portion of circuit may be hidden to the back side of the panel, thereby resulting in narrower lower frame area. Therefore, the lower frame area comprises a first main body on the front side, a bending region connected to the first main body, and a second main body bending to the back side to the display side by means of the bending region. When viewing from the front side, a bending axis of the bending region may form a lower edge of the display panel. The second main body may be disposed in parallel to the first main body to reduce the thickness of the touch display panel as much as possible. An intermediate film layer (not shown here) may be further provided between the first main body and the second main body to maintain the spacing therebetween. The length of the second main body on the back side of the touch display panel may be adjusted according to requirements. The FMLOC film is flexible, and the base display panel is flexible at least in the bending region.

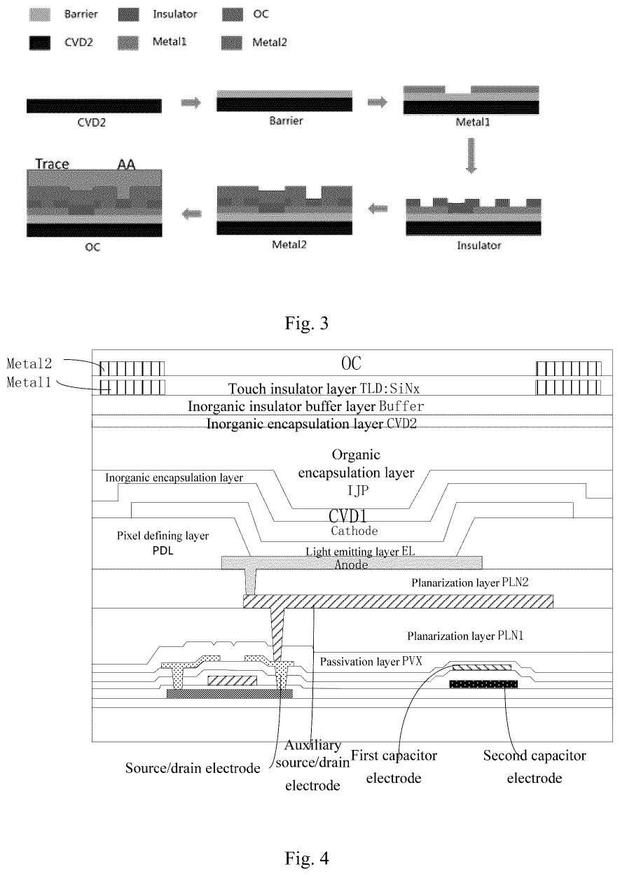

The multilayer structure of the FMLOC film must comprise a metal layer. The FMLOC film may comprise two metal layers disposed in layer, which are separated by an insulator layer, such that it is convenient to achieve a bridging between circuits in a region requiring touch control. FIG. 3 shows a schematic flow chart of an FMLOC process. After forming the last layer of encapsulation layer (CVD2) of the base display panel, a first film layer, i.e., a barrier layer (Barrier), of the FMLOC begins to be formed thereon, where the material used may be a silicon nitride (SiNx) material. Thereafter, a first metal layer (Metal 1) is formed, which may serve as a bridging film layer for a touch sensor (Sensor) for example, where the material used may be a Ti/Al/Ti tri-layer, an ITO/Ag/ITO tri-layer or the like. Subsequently, an insulator layer (Insulator) is formed, which serves as an insulator layer between two metal layers to prevent those two metal layers from being in contact with each other, where the material used may be a silicon nitride (SiNx) material. Thereafter, a second metal layer (Metal 2) is formed, which mainly serves as a wiring layer for a touch sensor (Sensor) for example, where the material used may be a Ti/Al/Ti tri-layer, an ITO/Ag/ITO tri-layer or the like. Finally, an overcoat layer (OC) is formed, where the material used may be polyimide (PI). In FIG. 3, AA represents the condition of the active area, i.e., the touch area, and Trace represents the trace line around the active area, i.e., in the frame area. In other words, the two metal layers, Metal 1 and Metal 2, form the trace line in the frame area, and form the touch electrode in the active area. FIG. 3 schematically shows in the active area that the first electrode layer may form a bridging layer for the second electrode layer. FIG. 3 is only illustrative. The FMLOC film may also have more film layers or less film layers, as long as it comprises necessary metal layers for forming electrodes and conductors.

The touch layer comprises a touch electrode disposed in the active area. FIG. 4 schematically shows a touch electrode on a pixel of the active area. The structure in the lower part of this figure is a common structure for a display panel, comprising a TFT and a light emitting unit driven by it. An encapsulation layer is provided on the light emitting unit. An FMLOC touch layer is formed on the inorganic encapsulation layer (CVD2), wherein metal layers (Metal 1 and Metal 2) separated by a touch insulator layer (TLD) are used for forming touch electrodes which may achieve the touch control function under an externally applied pressure.

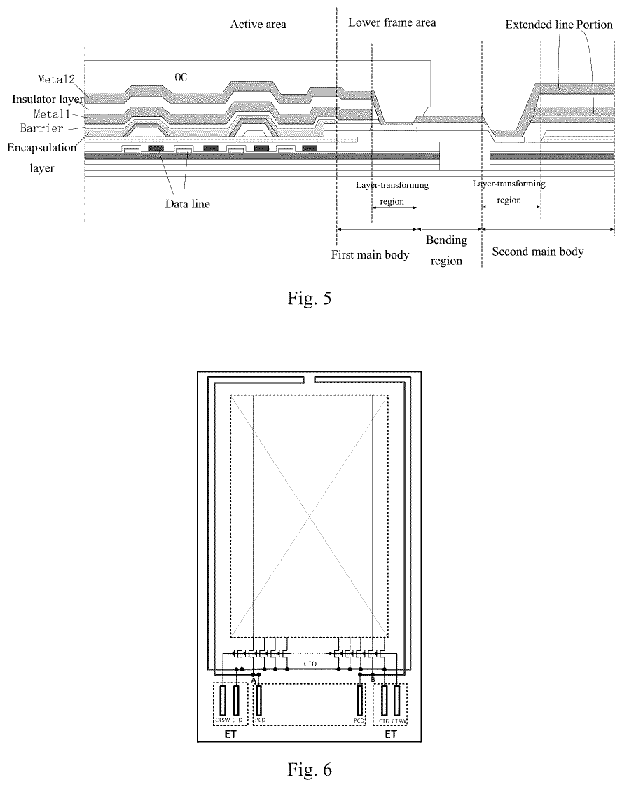

FIG. 5 shows a section view of an embodiment of an FMLOC touch panel when it is entirely unbent. In the left part, below the encapsulation layer, some display unit structures and the like of the base display panel are schematically shown. Specific structures may be similar to the base display panel as shown in FIG. 4 or other conventional base display panels. The portion above the encapsulation layer may comprise a five-layer FMLOC to form a touch electrode. A layer-transforming region is provided in the transition to the bending region, where two metal layers are transformed into a single layer conductive structure. After passing through the bending region, the single layer conductive structure is transformed back to the structure of two metal layers via another layer-transforming region. In other words, the conductive layer of the bending region may be different from those in the first main body and the second main body. Further, the line width thereof may also be different from those in the first main body and the second main body.

In the FMLOC PCD, the metal layer in the multiple film layers of the FMLOC film is used as the Panel Crack Detection line (PCD line). Typically, an end of the PCD line connected to a drive circuit is positioned in the lower frame area, and the PCD line starts from the lower frame area, runs on the periphery of the touch display panel, and then returns back to the lower frame area, such that when there is a crack extending from the edge of the display panel to the central active area, the presence of the crack is indicated by the PCD. In a design where the frame is provided on four sides, the PCD line may run in the frame area. If the design is the aforementioned full screen design, the PCD line may run in the back portion on the periphery of the touch display panel. Furthermore, in a display panel with a through hole in the active area (for example, a through hole for disposing a camera), it is also necessary to detect crack for the edge of the through hole. At this time, the PCD line may also be positioned around the through hole to indicate the crack extension from the edge of the through hole to the active area. In this case, the metal layer near the through hole of the active area is disconnected with the metal layer in other portions of the active area to form a PCD line, and this portion of PCD line may be connected to the PCD line in the peripheral wiring area of the panel to form a unitary crack detection circuit.

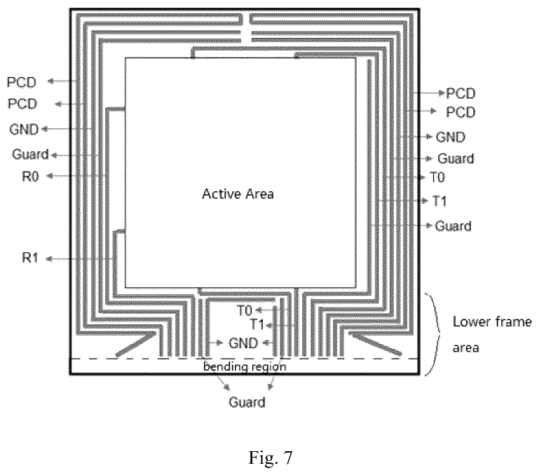

As described above, the design of the PCD circuit may be typically a resistance detection type or a bright line detection type. FIG. 6 shows a schematic principle diagram of a PCD examination for a typical base display panel. In this figure, the PCD line forms a loop substantially surrounding the active area. A data line and an input terminal connected to the pixels of the active area are provided in the lower frame. In an electrical test (ET), the CTSW switch is turned on, such that all the pixels of the central active area are in an “on” state, a high level data signal is written into the CTD terminal of the electrical test pin (ET PIN), the pixels directly connected to the CTD line will not emit light, and the panel displays a black picture. For the pixel connected to the node A and the node B, the data signal written into the CTD terminal will enter into the pixel after passing through the PCD line around the panel. If the PCD line is not broken, the data signal may successfully be written into the node A and the node B, and the entire panel presents a black picture. If the PCD line is broken, the data signal cannot be written into the node A and the node B, and the pixel connected to the node A and the node B is in a floating state, such that the panel will produce a bright line, the color of which depends on the sub-pixel connected to the node A and the node B. FIG. 6 also shows a resistance detection type, where whether the PCD line is broken is determined by writing a PCD signal via the PCD terminal and measuring the resistance of the PCD line between the test nodes A and B.

As shown in FIG. 6, the wiring area of the display panel is conventionally positioned in the lower frame of the panel. The PCD line may start from the lower frame area, run around the frame of the display panel to the center of the upper frame of the display panel, and then return back to the lower frame by the way it comes.

In the touch display panel, the PCD line may be formed from the metal layer in the touch layer. Specifically, in the lower frame area, the FMLOC film in the first main body comprises a Panel Crack Detection line formed from the metal layer in the FMLOC film. Because the metal layer in the FMLOC film is typically not connected to the circuit participating in the light emitting of the base display panel, the PCD of the present disclosure is typically performed in the aforementioned resistance measurement process rather than the bright line display process.

In the present disclosure, the touch layer comprises a touch electrode disposed in the active area, an trace line connected to the touch electrode and disposed in the frame area, and a crack detection line at a side of the trace line away from the active area, and in the first main body, the trace line comprises at least one conductive layer which is in the same layer as a conductive layer of the crack detection line. The crack detection line is at a side of the trace line away from the active area, that is, it surrounds the trace line, such that a crack intruding from outside may be detected. In the touch layer, the trace line comprises at least one conductive layer which is in the same layer as a conductive layer of the crack detection line. For example, both of them may comprise the aforementioned conductive layer of Metal 1 and/or conductive layer of Metal 2.

FIG. 7 schematically shows the line arrangement of lines formed from the metal layers of a typical FMLOC film in the frame area. When viewing from the front side, ends of a plurality of lines are collectively disposed above the bending region below. These lines comprise a trace line (trace), a ground line (GND), a guard line (Guard), a Panel Crack Detection line (PCD) and so on. The uppermost functional lines in the lower frame area are the trace lines, which are connected to different positions in the active area (i.e., the touch area) to achieve the touch control function. FIG. 7 schematically shows a wiring form of a common 2T1R mode. The trace lines connected to the touch area from the upper side and lower side of the active area are designated as Tx (such as T0 and T1), and the trace lines connected to the touch area from the left side of the active area are designated as Rx (such as R0 and R1). No matter how these trace lines are connected to the active area, their line terminals are converged above the bending region in the lower frame area. More specifically, starting from their line terminals, all the trace lines firstly run toward the lower edge of the active area, subsequently change direction, and run along the frame area outside the outer edge of the active area. For the purpose of saving lines, the terminals of the trace lines may be further divided, for example, they are located in two half areas, the left area and the right area, in the figure. A ground line (GND) surrounding the inside of the trace lines may be further provided between the left and right trace lines to provide protection. A guard line (Guard), a ground line (GND) and a Panel Crack Detection line (PCD) are further provided outside the trace lines (at the left side of the left trace line and at the right side of the right trace line). The guard line is a guard line which may be powered to provide electrical protection for other data lines in use. Generally, the same signal as applied to the adjacent guarded line is applied to the guard line. The guard line may also be disposed inside the trace line, for example, connected between the trace lines above and below the active area, or between the trace lines in the lateral frame area and the active area. Typically, in related technologies, the PCD line is located at the outermost side, and is arranged separately.

FIG. 7 also shows a position of the bending region corresponding to FIG. 1. The double layer structure is bent to the back side there, and the bending axis of the bending region forms the lower edge of the display panel. Thus, the second main body is not shown.

It is noted that the directions of various lines in the lower frame area in FIG. 7 are only illustrative.

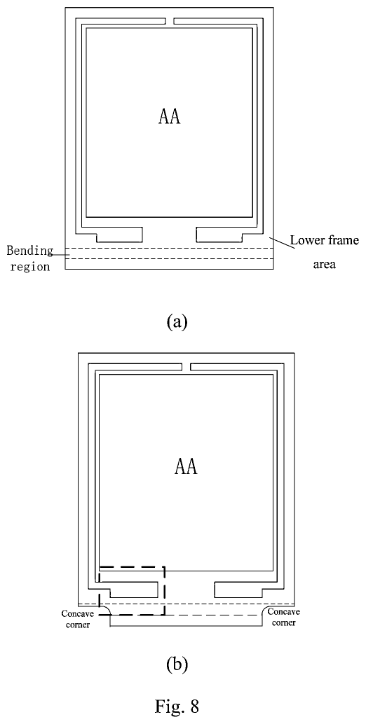

FIG. 8(a) shows a schematic diagram of a touch display panel having a bending region before bending. The grey portion schematically shows a wiring area comprising lines such as a trace line and a PCD line. Before bending, a planar double layer structure of base display panel-touch layer is firstly prepared. Then, the bending region in the lower portion is bent to the back side. The sectional structure of the unbent planar panel may be a structure schematically illustrated in FIG. 4 or FIG. 5 for example, or may be another common structure in related technologies.

FIG. 8(b) shows a variation of the unbent touch display panel as shown in FIG. 8(a) in practical production. At the left bottom and right bottom of the double layer structure, i.e., in the second main body, portions without lines are cut off to form two concave corners. The purpose of such cutting is that the portions of concave corners may not occupy the space on the back side after bending, which provides more space for accommodating other components (for example, other components of a mobile phone), to achieve thinning of the device. The concave corners in the figure are concave corners with an elliptical arc, but may also be concave corners with any other suitable shape, for example, a right angle, an obtuse angle, and a circular-arc-shaped concave corner. In the present disclosure, the concave corner refers to an unfilled corner formed by cutting off a portion of the double layer structure in the lower frame area of the unbent double layer structure. Such an unfilled floating has a lateral end surface recessed toward the center of the display panel.

The electrostatic discharge (ESD) immunity test is used to test the electrostatic discharge property of a display panel when it is close to or in contact with a person or an object. A qualified display panel product must pass the ESD test to ensure that it will not be damaged in use due to common electrostatic discharge. Conventionally, the ESD immunity test is performed by discharging on the front surface of the display panel.

The inventors of the present disclosure have surprisingly found that there is a certain possibility that the PCD cannot be normally completed on the FMLOC type touch display panel after the ESD test, and defects such as a bright line or a dark line sometimes occur, and the occurrence of those defects are not caused by the fluctuation of the preparation process.

After extensive research, the inventors have found that the occurrence of those defects is related to the initial design of the PCD wiring.

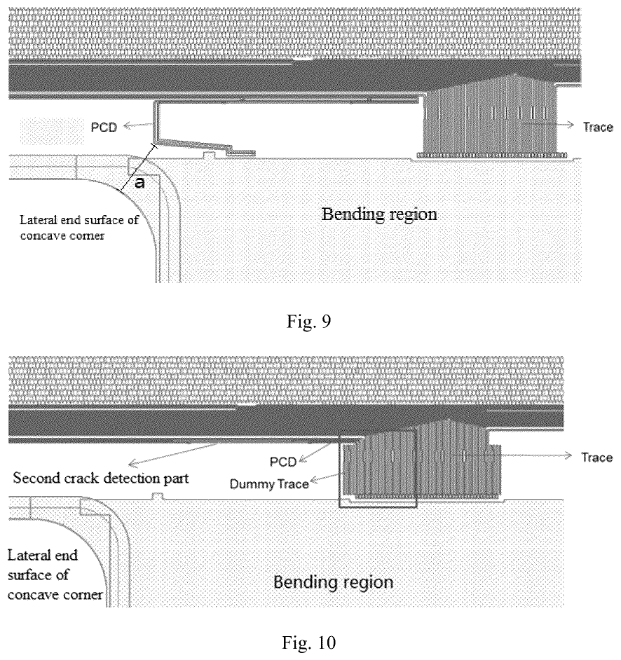

FIG. 9 shows a diagram of a general PCD line arrangement position in related technologies for the part in the dash line box at the left bottom of the lower frame as shown in FIG. 8(b). At the left bottom of the lower frame area, the wiring route of the PCD line is different from the wiring direction of other lines. Such a wiring approach follows the arrangement of a PCD line in a conventional non-FMLOC type touch display panel. As shown in the figure, the downward extending portion of the PCD line is far away from the vertical portion of the trace line, and also has a leftward (outward) protruding segment. According to such an arrangement, the PCD line has a wiring direction separated from those of other lines, and is arranged separately. It is much closer to the lateral end surface of the concave corner than the trace lines. The minimum distance between the PCD line and the lateral end surface of the concave corner is the distance a as shown in the figure. FIG. 9 is a schematic diagram, and is not drawn to according to actual scale.

After research, the inventors of the present disclosure have found that the defects occurred in the display panel having the PCD line design as shown in FIG. 9 after the ESD test may be caused by the following reasons. First, the PCD line itself is damaged during the ESD test, such that the PCD examination cannot be normally performed. Second, charges are accumulated after the PCD line is damaged, which in turn damages the electrical components or lines in the lower frame area whose projections are overlapped with that of the PCD line in the display panel, such as the GOA (Gate on Array, an integrated gate electrode) in the base display panel (also known as the back panel, BP). Third, because the PCD line itself is a conductor, charges may be transported along the PCD line from a portion with only the PCD line at the edge to a position where the PCD line is adjacent to other lines in the lower frame (for example, the upper area in FIG. 9), and damage other lines adjacent thereto, thereby resulting in defects such as occurrence of a bright line or a dark line in the active area. All these ESD damage issues occur in positions related to the PCD line. In contrast, the inventors have found that the above issues will not occur for the trace lines on the right side of FIG. 8.

With respect to the above issues, a modification is made based on a conventional FMLOC type touch display panel in the present disclosure. The basic structures in the FMLOC type touch display panel are similar to those in related technologies, except that particular positions for a specific PCD line arrangement are proposed.

In the touch display panel of the present disclosure, a group of wires in a first direction is provided in the lower frame area, wherein the first direction is a direction from the active area to the lower frame area, and the group of wires in the first direction comprises a trace part which is a portion of the trace line extending in the first direction, and a first crack detection part which is a portion of the crack detection line extending in the first direction;
wherein,
a maximum distance between the first crack detection part and the trace part is less than 10 times a width of the trace part in a direction perpendicular to its extending direction.

Surprisingly, after the above modification on the PCD wiring, the aforementioned defects related to ESD are significantly reduced. It is presumed that the aforementioned defects are related to the separate wiring approach of the PCD line. In other words, when the downward extending portion of the PCD line is disposed sufficiently close to the vertical portion of the trace line, i.e., the trace part, the occurrence rate of defects after ESD is significantly reduced. Without being bound to any theory, this is probably because the trace part shares the ESD shock on the downward extending portion of the PCD line to some extent.

In the present disclosure, the downward extending portion of the lower frame wiring area is referred to as the group of wires in the first direction, which comprises at least: a portion of the trace line extending in the first direction (referred to as the trace part), and a portion of the crack detection line extending in the first direction (referred to as the first crack detection part). Furthermore, the group of wires in the first direction may further comprise a guard line, a ground line, a dummy trace line as described below, and so on.

FIG. 10 shows a modified PCD line wiring arrangement based on FIG. 9. As can be seen, the original separately arranged downward extending portion of the PCD line is modified to be disposed adjacent to the trace line.

The first crack detection part is adjacent to the trace part to such an extent that a maximum distance between the first crack detection part and the trace part is less than 10 times a width of the trace part in a direction perpendicular to its extending direction. The trace part may comprise a plurality of electrode channel portions, and the distance here refers to a distance from the trace part closest to the first crack detection part. A width perpendicular to its extending direction is the line width of the trace part. When the distance between the first crack detection part and the trace part is less than 10 times its line width, the defects due to the ESD may be significantly reduced. Preferably, the distance is less than 5 times and more preferably 3 times its line width. Most preferably, the distance is the same as a distance between two neighboring electrode channel portions.

In an embodiment, the group of wires in the first direction further comprises a guard line, wherein the guard line comprises a conductive layer which is in the same layer as the conductive layer of the trace line, and is located between the first crack detection part and the trace part, an electrical signal the same as that of the trace line is input to the guard line.

The guard line is positioned inside the PCD line and outside the trace line to provide protection for the trace line. In the use of the display panel, the trace line inside the guard line may be protected by powering the guard line. The signal input to the guard line is the same as the signal of the trace line to be guarded thereby. For example, a regular square wave signal may be applied to the guard line to protect the lines inside it from being interfered externally.

In an embodiment, the group of wires in the first direction further comprises a ground line, wherein the ground line comprises a conductive layer which is in the same layer as the conductive layer of the trace line, and is at a side of the guard line away from the trace part.

The ground line is disposed outside the guard line, but may be disposed either inside or outside the PCD line. In the use of the display panel, it is grounded without being powered to provide ground protection for the trace line. The ground line and the guard line are different from the trace line, and neither of them is connected to the touch electrode in the active area.

In an embodiment, the group of wires in the first direction further comprises a dummy trace line, wherein the dummy trace line comprises a conductive layer which is in the same layer as the conductive layer of the first crack detection part, and is at a side of the first crack detection part away from the trace part, and the dummy trace line is floating.

The function of the dummy trace line is to further reduce the direct effect of electrostatic discharge on the PCD line. The dummy trace line does not function as a circuit in the display panel, but is only an electrically floating isolated line disposed outside the PCD line. By providing the dummy trace line, the electrostatic shock effect may be partially borne by the dummy trace line before arriving at the PCD line. Furthermore, the dummy trace line also functions to physically protect lines inside it. Also, the dummy trace line becomes a line at the edge, which is also advantageous for ensuring the precision of internal lines in the preparation by etching.

Preferably, a number of the dummy trace line is 2 or more. The larger the number of the dummy electrode channel portion, the better the protection effect on the PCD is.

Preferably, all the lines in the group of wires in the first direction have the same line width and the same line distance. In other words, the trace line, the guard line, the ground line, the Panel Crack Detection line and the dummy trace line have a plurality of line segments with the same width which are arranged in parallel at the same distance. As shown in FIG. 9, these line segments are arranged vertically, and connected to the line terminals. The line terminals may be connected to an external circuit via a through hole in the lower frame area. Generally, a part of the trace line may comprise a plurality of line segments with the same width which are arranged in parallel at the same distance. For example, the lower frame area may have a region in which the vertical segments of a plurality of trace lines are arranged, and these vertical segments are lines with the same width which are arranged at the same distance. Preferably, the line width is in a range from 10 nm to 30 nm, and the distance is in a range from 15 nm to 30 nm. Such line width and distance achieve a better balance between the process difficulty and the performance. In this case, the PCD lines and so on are also designed to be lines with the same width, and are also arranged in parallel at the same distance outside the trace line. The design of parallel, equal distance and equal width line segments may provide a uniform line distribution, which further reduces the possibility of electrostatic damage. Also, such a design of line segments is also beneficial for easy actual production by an etching process. In contrast, non-uniform line combination increases potential risk of electrostatic damage and is difficult to be prepared. It should be understood that when some lines are absent, for example, the dummy trace line or the guard line is absent, remaining lines are still arranged in parallel at the same distance outside a plurality of trace lines.

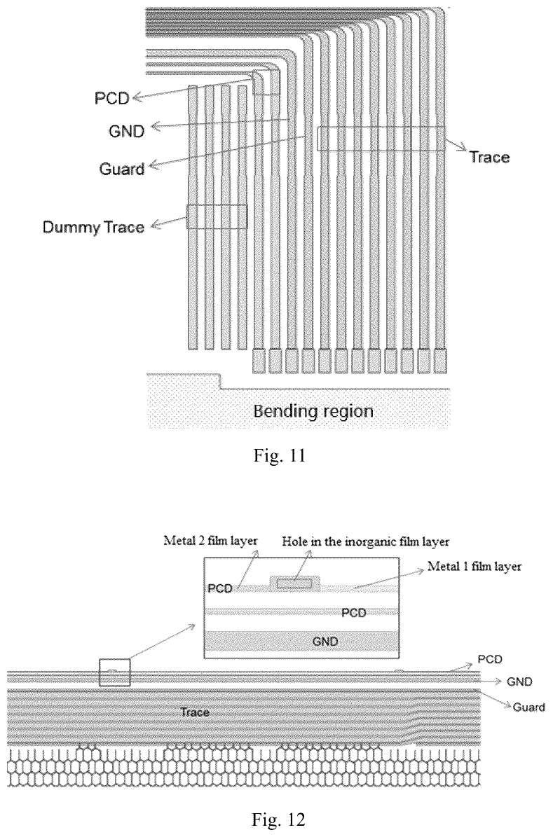

FIG. 11 shows an enlarged view of the box area in FIG. 10. As shown in FIG. 11, the right side is a plurality of trace lines with the same width which are arranged in parallel at the same distance. At the left side of the trace lines, a guard line, a ground line, a Panel Crack Detection line and a dummy trace line which have the same width are sequentially arranged in parallel at the same distance. It should be noted that the ground line may be either inside or outside the Panel Crack Detection line. The lower ends of these vertical parallel lines are terminal portions. As shown in FIG. 10, the terminal portions are arranged in the same straight line. Such a specific design is orderly and beneficial for easy production, and sufficiently reduces the defects due to the ESD test. Therefore, preferably, the plurality of line segments with the same width which are arranged in parallel at the same distance are perpendicular to the bending axis of the bending region.

The touch layer preferably comprises two metal layers, particularly a first metal layer, an insulator layer and a second metal layer stacked one on top of another, i.e., the structure of an FMLOC film. The touch layer may further comprise other additional film layers, such as a protection layer, a buffer layer, and a barrier layer.

In an embodiment, the trace part may comprise a first metal layer and a second metal layer connected in parallel, and the first crack detection part comprises at least one layer of the first metal layer and the second metal layer. In other words, the trace part utilizes both the first metal layer and the second metal layer to increase its conductive property, while the first crack detection part may only comprise one of those two metal layers.

In an embodiment, the crack detection line comprises a second crack detection part at a side of the first crack detection part away from the bending region, wherein the second crack detection part is connected to the first crack detection part and extends in a second direction substantially perpendicular to the first direction; and
the second crack detection part comprises a first line segment and a second line segment alternately disposed in different layers, wherein an end of the first line segment and an end of the second line segment are overlapped with each other, and electrically connected to each other through a via hole in an insulator layer between the layers.

Outside the first crack detection part, the crack detection line conventionally runs in parallel to the trace lines in a route surrounding the active area. In particular, in the lower frame area, the crack detection line will turn to run in a lateral direction below the active area. As shown in FIG. 10, the laterally running portion is referred to as the second crack detection part to be distinct from the first crack detection part. In such a laterally running second crack detection part, if the line is too long, the defect due to the ESD is likely to occur. In an embodiment, multiple jumpers are designed in the PCD wiring to reduce the risk of defects due to the ESD, the jumpers are jumping between the first metal layer and the second metal layer of the FMLOC film, and those two metal layers are connected to each other via a hole opening through the inorganic layer. Specifically, from bottom to top, the FMLOC film comprises a barrier layer, a first metal layer, an insulator layer, a second metal layer and an overcoat layer, wherein the Panel Crack Detection line comprises alternately a line segment in the first metal layer and a line segment in the second metal layer, and the line segment in the first metal layer and the line segment in the second metal layer are connected to each other by a jumper penetrating the insulator layer. The position of the jumper is as schematically shown in FIG. 12. In the figure, the upper side is the edge direction of the display panel, and the lower side is the central direction of the display panel. The position of the PCD line in the lower frame area is combined with the jumper treatment on the PCD line in another frame area, which may further reduce the defects due to the ESD test. The line segment in the first metal layer and the line segment in the second metal layer may have a length greater than 100 microns. Such a length range (or a jumper distance) may sufficiently reduce the possibility of ESD damage on the periphery of the display panel, and may not overly increase the process difficulty in the FMLOC patterning and the formation of a multilayer structure. Also, even when the double layer structure also has no overcoat layer on the lateral end surface of the frame area and the distance from the PCD line to the lateral end surface is small, this jumper design may also provide effective protection for the ESD.

In an embodiment, the touch display panel comprises an extension line part extending from at least a portion of lines in the group of wires in the first direction to the second main body. Preferably, all lines other than the dummy trace line have an extended line portion which crosses over the bending region and is connected to the circuit on the back side of the touch display panel. Preferably, corresponding line in the extended line portion has the same line width and the same line distance as in the original line. This is advantageous for maintaining the effect of reduced ESD defects. The extended line portion may an extended line as shown in FIG. 5. It is connected to the group of wires in the first direction in the first main body via the circuit of the bending region.

In an embodiment, the base display panel comprises a display structure and an encapsulation layer on the display structure, and the touch layer is disposed on the encapsulation layer. The encapsulation layer functions to provide a planarization base surface and protect the display structure. The display structure may comprise, for example, an OLED light emitting unit and a TFT substrate below it.

Further, without being bound by any theory, the separate wiring of the PCD line following a conventional wiring approach in related technologies is too close to the lateral end surface of the concave corner of the double layer structure of the FMLOC film and the base display substrate, which may also result in that the ESD is more easily introduced and causes the above-mentioned defects. Such a finding is surprising, because the ESD test is performed on the front side of the display panel, and seems to be independent of the distance between the PCD line and the lateral end surface of the concave corner. However, the concave corner has a curvature radius recessed toward the interior of the display panel, which may form a region that will be easily intruded by electrostatic charges. Further, the concave corner is formed by a double layer structure cutting process. In a conventional process, the lateral end surface is a freshly cut surface without any post-treatment, which may also be a weakness that will be easily intruded by electrostatic charges. Also, as compared to an FMLOC type display panel, the interface between film layers of the FMLOC film in the double layer structure and the binding surface between the FMLOC film and the base display panel may also provide a route for electrostatic charge intrusion.

Therefore, in the case where there is a concave corner, the aforementioned defects produced after the ESD test are further reduced by configuring the PCD line in the lower frame to be far away from the lateral end surface of the concave corner. The inventors of the present disclosure have found that the defects during the ESD test may be further reduced by setting the distance between the Panel Crack Detection line and the lateral end surface of the concave corner to be 0.8 mm or more. The distance here is measured when the double layer structure is not bent. For example, the minimum distance between the PCD line and the lateral end surface of the concave corner is measured in the unbent state as shown in FIG. 8(b). Larger distance is better. For example, the distance is preferably 0.9 mm or more, and more preferably 1.0 mm or more, but should also meet the requirements for the narrow frame design of the lower frame area. When the distance is less than 0.8 mm, the effect of the concave corner may not be sufficiently avoided.

The present disclosure also provides a display device comprising the touch display panel as described above, and the display device has the same advantages as the touch display panel accordingly. Furthermore, when the bending region of the touch display panel has a concave corner, the space left may be used for placing other components of the display panel to save space and reduce the thickness and volume of the display device. Examples of the display device may comprise a mobile phone, particularly a mobile phone with a narrow frame.

The present disclosure will be further described below with reference to the Comparative Example and the Examples.

### Comparative Example 1

An FMLOC film layer comprising a barrier layer, a first metal layer, an insulator layer, a second metal layer and an overcoat layer was formed on a display panel, to form a double layer structure. Patterning was carried out when forming two film layers of metal layers in the FMLOC to form a touch electrode and a bridging line in the active area, and an electrode channel, a PCD line, a guard line and a ground line in the frame area. Here, the touch electrode was formed from the second metal layer, the bridging line was formed from the first metal layer, the trace line, the guard line and the ground line were formed from both the first metal layer and the second metal layer, and the PCD line was formed from the first metal layer in the entire frame area.

Two corners at the bottom of the double layer structure were cut off to form a circular-arc-shaped concave corner, thereby forming an unbent double layer structure as shown in FIG. 8 (b).

The line distribution is as shown in FIG. 9, where the PCD line is separately arranged. The trace lines (the trace part) comprised a plurality of lines with a line width of 20 nm and a line distance of 20 nm. The maximum distance between the PCD line and the left-most trace line was 300 nm. Furthermore, the distance “a” between the PCD line and the concave corner formed by cutting off a corner was less than 0.8 mm.

The bending region in the lower part of the double layer structure was bent to bend the second main body to the back side. Subsequently, an ESD test was performed.

A PCD examination was performed in the resistance detection manner after the ESD test. Furthermore, a lighting on test was performed.

1000 products were examined, the total defect ratio where the PCD examination cannot be performed or a bright line or a dark line exists was counted to be about 5%.

### Example 1

The display panel was prepared in the same way as in Comparative Example 1, only except that the PCD line arrangement in the lower frame area was similar to FIG. 10 but without disposing a dummy trace line. A first crack detection part, a trace part, a guard line and a ground line forming a group of wires in a first direction all have parallel line segments with the same width. That is, all the line width was 20 nm, and all the distance was 20 nm. After the direction is changed, the minimum distance between the PCD line and the lateral end surface of the concave corner formed by cutting off a corner was greater than 0.8 mm.

The bending, the ESD test, the PCD examination and the lighting on test were also performed. 1000 products were examined, the total defect ratio where the PCD examination cannot be performed or a bright line or a dark line exists was counted to be less than 1%.

### Example 2

The display panel was prepared in the same way as in Example 1, except that four dummy trace lines were additionally provided for the PCD line in the lower frame area as shown in FIG. 10. A first crack detection part, a trace part, a guard line, a ground line and the dummy trace lines forming a group of wires in a first direction all have parallel line segments with the same width. That is, all the line width was 20 nm, and all the distance was 20 nm. After the direction is changed, the minimum distance between the PCD line and the lateral end surface where a corner was cut off was greater than 0.8 mm.

The bending, the ESD test, the PCD examination and the lighting on test were also performed. 1000 products were examined, the total defect ratio where the PCD examination cannot be performed or a bright line or a dark line exists was counted to be less than 0.5%.

### Example 3

The display panel was prepared in the same way as in Example 2, only except that the lateral PCD line below the active area and in parallel to the edge of the active area comprised alternately a line segment in the first metal layer and a line segment in the second metal layer which were connected to each other via a jumper penetrating the insulator layer. The jumper distance was 150 microns.

The bending, the ESD test, the PCD examination and the lighting on test were also performed. 1000 products were examined, no defect where the PCD examination cannot be performed or a bright line or a dark line exists was found, and thus the defect ratio was 0%.

As can be seen from the Comparative Example and the Examples, the Panel Crack Detection line design of the present disclosure may effectively ameliorate the shock damage and short circuit in the PCD line and the trace line of the FMLOC in the touch display panel comprising an FMLOC film and reduce the defects caused after the electrostatic damage examination.

The above descriptions are only particular embodiments of the present disclosure, but the protection scope of the present disclosure is not limited thereto. Within the technical scope disclosed in the present disclosure, one skilled in the art can readily envisage variations and alternatives, and all of them are covered by the protection scope of the present disclosure. Therefore, the protection scope of the present disclosure should be defined by the appended claims.

1. A touch display panel, wherein
the touch display panel comprises an active area and a frame area surrounding the active area, wherein the frame area comprises a lower frame area below the active area, the lower frame area of the touch display panel comprises a first main body, a bending region and a second main body, and the second main body is bent to a back side opposite to a display side of the touch display panel,
the touch display panel comprises a base display panel and a touch layer on the base display panel, wherein the touch layer comprises a touch electrode disposed in the active area, an trace line connected to the touch electrode and disposed in the frame area, and a crack detection line at a side of the trace line away from the active area, and in the first main body, the trace line comprises at least one conductive layer which is in the same layer as a conductive layer of the crack detection line, and
there is a group of wires in a first direction in the first main body, wherein the first direction is a direction from the active area to the lower frame area, and the group of wires in the first direction comprises a trace part which is a portion of the trace line extending in the first direction, and a first crack detection part which is a portion of the crack detection line extending in the first direction;
wherein a maximum distance between the first crack detection part and the trace part is less than 10 times a width of the trace part in a direction perpendicular to its extending direction.

2. The touch display panel according to claim 1, wherein the group of wires in the first direction further comprises a guard line, wherein the guard line comprises a conductive layer which is in the same layer as the conductive layer of the trace line, and is located between the first crack detection part and the trace part, an electrical signal the same as that of the trace line is input to the guard line.

3. The touch display panel according to claim 2, wherein the group of wires in the first direction further comprises a ground line, wherein the ground line comprises a conductive layer which is in the same layer as the conductive layer of the trace line, and is at a side of the guard line away from the trace part.

4. The touch display panel according to claim 1, wherein the group of wires in the first direction further comprises a dummy trace line, wherein the dummy trace line comprises a conductive layer which is in the same layer as the conductive layer of the first crack detection part, and is at a side of the first crack detection part away from the trace part, and the dummy trace line is electrically floating.

5. The touch display panel according to claim 4, wherein a number of the dummy trace line is 2 or more.

6. The touch display panel according to claim 1, wherein all the lines in the group of wires in the first direction have the same line width and the same line distance.

7. The touch display panel according to claim 6, wherein the line width is between 10 nm and 30 nm, and the line distance is between 15 nm and 30 nm.

8. The touch display panel according to claim 1, wherein the first direction is perpendicular to a bending axis of the bending region.

9. The touch display panel according to claim 1, wherein the touch layer comprises a first metal layer, an insulator layer and a second metal layer stacked one on top of another.

10. The touch display panel according to claim 9, wherein the trace part comprises a first metal layer and a second metal layer connected in parallel, and the first crack detection part comprises at least one layer of the first metal layer and the second metal layer.

11. The touch display panel according to claim 1, wherein the crack detection line comprises a second crack detection part at a side of the first crack detection part away from the bending region, wherein the second crack detection part is connected to the first crack detection part and extends in a second direction substantially perpendicular to the first direction; and
the second crack detection part comprises a first line segment and a second line segment alternately disposed in different layers, wherein an end of the first line segment and an end of the second line segment are overlapped with each other, and electrically connected to each other through a via hole in an insulator layer between the layers.

12. The touch display panel according to claim 1, wherein the touch display panel comprises an extension line part extending from at least a portion of lines in the group of wires in the first direction to the second main body.

13. The touch display panel according to claim 1, wherein the base display panel comprises a display structure and an encapsulation layer on the display structure, and the touch layer is disposed on the encapsulation layer.

14. The touch display panel according to claim 1, wherein the second main body has a concave corner, and when the touch display panel is in an unbent state, a distance between the crack detection line and the concave corner is 0.8 mm or more.

15. A display device comprising the touch display panel according to claim 1.
